(19) United States
(12) Patent Application Publication
(10) Pub. No.: US 2025/0174521 A9
(43) Pub. Date: May 29, 2025

(54) SEMICONDUCTOR PACKAGE INCLUDING HEAT RADIATION STRUCTURE, COOLING SYSTEM APPLYING THE SEMICONDUCTOR PACKAGE, SUBSTRATE INCLUDING HEAT RADIATION STRUCTURE AND METHOD OF MANUFACTURING THE SUBSTRATE

(71) Applicant: JMJ Korea Co., Ltd., Bucheon-si (KR)

(72) Inventor: Yun Hwa CHOI, Bucheon-si (KR)

(73) Assignee: JMJ Korea Co., Ltd., Bucheon-si (KR)

(21) Appl. No.: 17/964,032

(22) Filed: Oct. 12, 2022

(30) Foreign Application Priority Data
Feb. 21, 2022 (KR) 10-2022-0022350

(51) Int. Cl. H01L 23/473; H01L 21/48; H01L 23/00; H01L 23/367; H01L 23/498

(52) U.S. Cl. CPC H01L 23/473; H01L 21/4882; H01L 23/3672; H01L 23/3677; H01L 23/49811; H01L 23/49822; H01L 23/49833; H01L 23/49844; H01L 24/32; H01L 24/40; H01L 24/48; H01L 24/73; H01L 2224/32225; H01L 2224/32245; H01L 2224/40155; H01L 2224/48155; H01L 2224/73215; H01L 2224/73263; H01L 2224/73265; H01L 2924/1811; H01L 2924/1815; H01L 2924/182

(57) ABSTRACT

Provided is a semiconductor package including a heat radiation structure, a cooling system applying the semiconductor package, a substrate including a heat radiation structure, and a method of manufacturing the substrate, and more particularly, a semiconductor package including a heat radiation structure, a cooling system applying the semiconductor package, a substrate including a heat radiation structure, and a method of manufacturing the substrate, in which an area contacting a coolant enlarges through heat radiating posts having various forms and structures and a coolant flow path is formed by post holes so that heat generated from semiconductor chips may be efficiently cooled.

### CROSS-REFERENCE TO RELATED PATENT APPLICATION

This application claims the benefit of Korean Patent Application No. 10-2022-0022350, filed on Feb. 21, 2022, in the Korean Intellectual Property Office, the disclosure of which is incorporated herein in its entirety by reference.

### BACKGROUND OF THE INVENTION

### 1. Field of the Invention

The present invention relates to a semiconductor package including a heat radiation structure, a cooling system applying the semiconductor package, a substrate including a heat radiation structure, and a method of manufacturing the substrate, and more particularly, to a semiconductor package including a heat radiation structure, a cooling system applying the semiconductor package, a substrate including a heat radiation structure, and a method of manufacturing the substrate, in which an area contacting a coolant enlarges through heat radiating posts having various forms and structures and a coolant flow path is formed by post holes so that heat generated from semiconductor chips may be efficiently cooled.

### 2. Description of the Related Art

As well known in the art, electrical and electronic components, in particular, semiconductor components, generate excessive heat while being operated and thus, a heat sink or a cooling system is needed to prevent overheating so as to maintain their performance.

Particularly, semiconductor components applied to a high-power application field may efficiently prevent overheating by using a cooling system which circulates a coolant.

The cooling system includes posts inserted thereto for contacting a circulating coolant and cools heat transmitted from the semiconductor components to the posts. In general, the posts are formed as in one body with an upper substrate and/or a lower substrate included in the cooling system by a manufacturing process or a casting production process and thus, mostly have a linear structure.

That is, the posts having a simple linear structure still have limitations in maximizing heat conductivity effect or heat radiation effect. Accordingly, heat radiating posts having various forms and structures are needed to enlarge an area contacting a coolant and thereby, to improve heat conductivity effect and heat radiation effect using a cooling method directly by a coolant.

### SUMMARY OF THE INVENTION

The present invention provides a semiconductor package including a heat radiation structure, a cooling system applying the semiconductor package, a substrate including a heat radiation structure, and a method of manufacturing the substrate, in which an area contacting a coolant enlarges through heat radiating posts having various forms and structures and a coolant flow path is formed by post holes so that heat generated from semiconductor chips may be efficiently cooled.

According to an aspect of the present invention, there is provided a semiconductor package having a heat radiation structure including: at least one substrate comprising a heat radiating metal layer, to which heat radiating posts are structurally joined, and at least one insulating layer; at least one semiconductor chip comprising a lower surface bonded to the substrate and an upper surface electrically connected to a terminal lead through an electrical signal line; and a molding housing covering the semiconductor chips, a part of the terminal lead, and a part of or the entire substrate, wherein the heat radiating posts are formed to be exposed to the upper surface, the lower surface, or the upper and lower surfaces of the molding housing, an area of the insulating layer is larger than an area of the heat radiating metal layer, the insulating layer is extended outward from the edge of the heat radiating metal layer by a predetermined extended distance in the molding housing, a distance from the bottom of the insulating layer to the bottom of the molding housing, where the heat radiating posts are exposed, is 40 μm through 4 mm, at least one post hole is interposed between the heat radiating posts which are arranged and spaced apart from each other by a regular interval so as to form a coolant flow path, and a coolant of a cooling system used to cool heat generated from the semiconductor chips circulates the coolant flow path.

The at least one substrate may include the at least one heat radiating metal layer, the insulating layer stacked on the heat radiating metal layer, and a metal pattern layer comprising the semiconductor chips installed thereon which is stacked on the insulating layer.

A metal adhesive layer having a thickness thinner than the thickness of the metal pattern layer or the heat radiating metal layer may be interposed between the insulating layer and the metal pattern layer or between the insulating layer and the heat radiating metal layer.

The heat radiating posts may be formed by being masked using a screen mask or a stencil mask, printing metal paste or non-metal paste onto the heat radiating metal layer, and then, being hardened.

The heat radiating posts may be a solder containing Sn ingredient, may be formed of a single material including Al, Cu, or ceramic, or may be formed of a composite material containing 50% or more of any one of Sn, Al, Cu, and ceramic.

The heat radiating metal layer and the heat radiating posts may include an adhesive layer interposed therebetween to be joined to each other.

The adhesive layer may be formed of a single material including Ag, Au, Cu, Ti, Ni, Pd, or ceramic or a composite material containing 50% or more of any one of Ag, Au, Cu, Ti, Ni, Pd, and ceramic.

The heat radiating posts may have at least one wave-form structure where the crest of the wave is joined to the bottom surface of the heat radiating metal layer and at least one post hole may be formed between each neighbored crest between the heat radiating metal layer and the wave-form structure.

The wave-form structure may be bonded to the heat radiating metal layer by using ultrasonic welding.

The at least one heat radiating post may include at least one post connecting frame structurally joined to one surface thereof to form a post connection part.

The heat radiating posts may include adhesive layers on the upper surfaces, the lower surfaces, or the upper and lower surfaces thereof.

The post connecting frame may include an adhesive layer on the upper surface thereof.

The heat radiating metal layer may include at least one layered post connection part stacked on the bottom surface thereof.

The distance between the heat radiating metal layer and the heat radiating posts may be 10 μm through 3 mm.

A first distance from the lower end part of the insulating layer to the upper end part of the heat radiating metal layer may be shorter than a second distance from the lower end part of the insulating layer to the lower end part of the heat radiating metal layer.

A gap between the first distance and the second distance may be 1 μm through 200 μm.

The molding housing may be formed of a composite material containing an epoxy component.

The semiconductor chip may be a metal-oxide semiconductor field-effect transistor (MOSFET), an insulated gate bipolar transistor (IGBT), or a semiconductor device for converting power including a Gallium Nitride (GaN), Silicon Carbide (SiC), or Gallium (Ga).

The post connecting frame may be inserted into the cooling system.

The electrical signal line may be a wire, a metal clip, or a metal spacer.

The heat radiating metal layer may be may be formed of a single material including Au, Cu, Al, or Ni, an alloy material containing 50% or more of any one of Au, Cu, Al, and Ni, or a metal material having a multilayered structure including the single material or the alloy material.

The heat radiating metal layer and the heat radiating posts may be formed of the same material.

The extended distance may be 5 μm through 3 mm.

The insulating layer may be formed of a single material including Al₂O₃, AlN, Si₃N₄, or PI or a composite material containing any one of Al₂O₃, AlN, Si₃N₄, and Pl.

The heat radiating posts may be joined to the substrate after a molding process of the molding housing.

The coolant may be cooling water, cooling liquid containing cooling water, air, or nitrogen or may include any one of cooling water, cooling liquid containing cooling water, air, and nitrogen.

According to another aspect of the present invention, there is provided a cooling system to which the semiconductor package including a heat radiation structure described above is joined.

According to another aspect of the present invention, there is provided a

substrate having a heat radiating structure including: a heat radiating metal layer to which heat radiating posts are structurally joined; and the at least one insulating layer stacked on the heat radiating metal layer, wherein an area of the insulating layer is larger than an area of the heat radiating metal layer, the insulating layer is extended outward from the edge of the heat radiating metal layer by a predetermined extended distance, at least one post hole is interposed between the heat radiating posts which are arranged and spaced apart from each other by a regular interval so as to form a coolant flow path, and a coolant of a cooling system circulates the coolant flow path.

According to another aspect of the present invention, there is provided a method of manufacturing a substrate having a heat radiating structure including: preparing at least one insulating layer; forming a heat radiating metal layer on one surface of the insulating layer; and structurally joining the heat radiating posts to the heat radiating metal layer, wherein an area of the insulating layer is larger than an area of the heat radiating metal layer, the insulating layer is extended outward from the edge of the heat radiating metal layer by a predetermined extended distance, at least one post hole is interposed between the heat radiating posts which are arranged and spaced apart from each other by a regular interval so as to form a coolant flow path, and a coolant of a cooling system circulates the coolant flow path.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a semiconductor package including a heat radiation structure according to an embodiment of the present invention;

FIGS. 2A through 4C illustrate various assembling structures of heat radiating posts in the semiconductor package including a heat radiation structure of FIG. 1;

FIGS. 5A and 5B illustrate various structures of the semiconductor package including a heat radiation of FIG. 1;

FIGS. 6A and 6B illustrate a cooling structure between the semiconductor package including a heat radiation of FIG. 1 and a cooling system; and

FIG. 7 is a flowchart schematically illustrating a method of manufacturing a substrate including a heat radiation structure according to another embodiment of the present invention.

### DETAILED DESCRIPTION OF THE INVENTION

Hereinafter, the present invention will be described in more detail with reference to the accompanying drawings.

A semiconductor package including a heat radiation structure according to an embodiment of the present invention includes a heat radiating metal layer 121 to which heat radiating posts 111 are structurally joined, at least one substrate 120 including at least one insulating layer 122, at least one semiconductor chip 130 including a lower surface bonded to the substrate 120 and an upper surface electrically connected to a terminal lead 132 through an electrical signal line, and a molding housing 140 covering the semiconductor chips 130, a part of the terminal lead 132, and a part of or the entire substrate 120, wherein the heat radiating posts 111 are formed to be exposed to the upper surface, the lower surface, or the upper and lower surfaces of the molding housing 140, an area of the insulating layer 122 is larger than an area of the heat radiating metal layer 121, the insulating layer 122 is extended outward from the edge of the heat radiating metal layer 121 by a predetermined extended distance D1 in the molding housing 140, a distance D2 from the bottom of the insulating layer 122 to the bottom of the molding housing 140, where the heat radiating posts 111 are exposed, is 40 μm through 4 mm, at least one post hole 112 is interposed between the heat radiating posts 111 which are arranged and spaced apart from each other by a regular interval so as to form a coolant flow path, and a coolant of a cooling system 150 used to cool heat generated from the semiconductor chips 130 circulates the coolant flow path. Accordingly, an area contacting the coolant is enlarged through the heat radiating posts 111 having various forms and structures and thereby, heat generated from the semiconductor chips 130 may be efficiently cooled.

Hereinafter, the semiconductor package including a heat radiation structure will be described in more detail with reference to the accompanying drawings.

Firstly, the heat radiating posts 111 are structurally joined to the heat radiating metal layer 121 and thereby, transmit heat from the semiconductor chips 130 to the outside of the substrate 120.

The heat radiating posts 111 may be joined to the substrate 120 after a molding process of the molding housing 140.

Next, the at least one substrate 120 includes the at least one insulating layer 122.

Here, the substrate 120 may include at least one heat radiating metal layer 121, the insulating layer 122 stacked on the heat radiating metal layer 121, and a metal pattern layer 123 stacked on the insulating layer 122, wherein the metal pattern layer 123 includes the semiconductor chips 130 installed thereon.

A metal adhesive layer (not illustrated) having a thickness of below 100 μm which is thinner than the thickness of the metal pattern layer 123 or the heat radiating metal layer 121 may be interposed between the insulating layer 122 and the metal pattern layer 123 or between the insulating layer 122 and the heat radiating metal layer 121 and may be bonded to each other.

Also, the heat radiating metal layer 121 may be formed of a single material including Au, Cu, Al, or Ni, an alloy material containing 50% or more of any one of Au, Cu, Al, and Ni, or a metal material having a multilayered structure including a single material or an alloy material. Here, the heat radiating metal layer 121 and the heat radiating posts 111 may be formed of the same material.

In addition, the insulating layer 122 may be formed of a single material including Al₂O₃, AlN, Si₃N₄, or PI or a composite material containing any one of Al₂O₃, AlN, Si₃N₄, and Pl.

Next, the lower surfaces of the at least one semiconductor chip 130 are joined to the substrate 120 and the upper surfaces of the at least one semiconductor chip 130 are electrically connected to the terminal lead 132 through an electrical signal line 131 so that an electrical signal may be applied.

Here, the semiconductor chip 130 may be a metal-oxide semiconductor field-effect transistor (MOSFET), an insulated gate bipolar transistor (IGBT), or a semiconductor device for converting power including a Gallium Nitride (GaN), Silicon Carbide (SiC), or Gallium (Ga) and may be applied to a device such as an inverter, a converter, or an on board charger (OBC) which is used to convert or control power. Since excessive heat is generated while power is converted into power having a specific current, a specific voltage, or a specific frequency and thus, heat is cooled through the cooling system 150.

Next, the molding housing 140 covers the semiconductor chips 130, a part of the terminal lead 132, and a part of or the entire substrate 120 and may be formed by being hardened into a composite material containing an epoxy component.

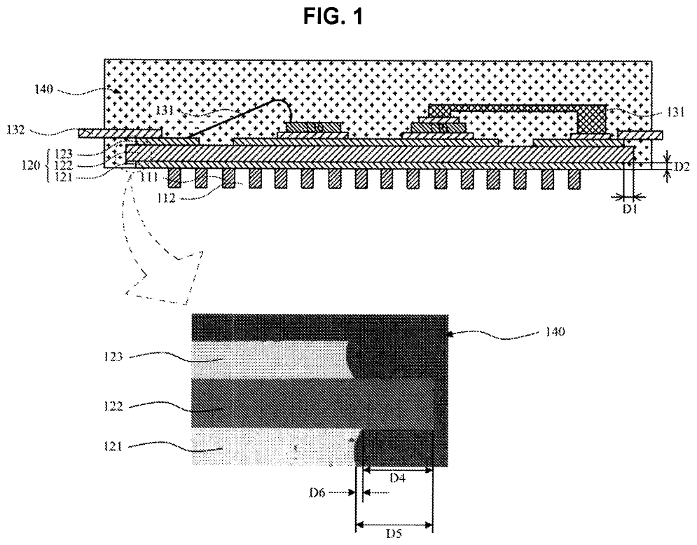

Here, referring to FIG. 1, the heat radiating posts 111 are formed to be exposed to the upper surface, the lower surface, or the upper and lower surfaces of the molding housing 140, an area of the insulating layer 122 is larger than an area of the heat radiating metal layer 121, the insulating layer 122 is extended outward from the edge of the heat radiating metal layer 121 by the extended distance D1 of 5 μm through 3 mm in the molding housing 140, the distance D2 from the bottom of the insulating layer 122 to the bottom of the molding housing 140, where the heat radiating posts 111 are exposed, is 40 μm through 4 mm, at least one post hole 112 is interposed between the heat radiating posts 111 which are arranged and spaced apart from each other by a regular interval so as to form the coolant flow path, and a coolant of the cooling system 150 used to cool heat generated from the semiconductor chips 130 circulates the coolant flow path. Accordingly, a heat radiating area may be enlarged through the heat radiating posts 111 and the heat radiating posts 111 may be directly cooled by a coolant so as to improve cooling efficiency. Also, the heat radiating metal layer 121 is covered by the insulating layer 122 so that heat transmitted to the heat radiating posts 111 may not be retransmitted and thus, the semiconductor chips 130 may be protected from a high temperature.

In addition, the coolant circulating an inlet and an outlet of the cooling system 150 may be a coolant fluid, refrigerant gas, and/or air (cold air).

Here, the coolant may be selected from any one of cooling water, cooling liquid containing cooling water, air (cold air), and nitrogen or may include any one of cooling water, cooling liquid containing cooling water, air (cold air), and nitrogen.

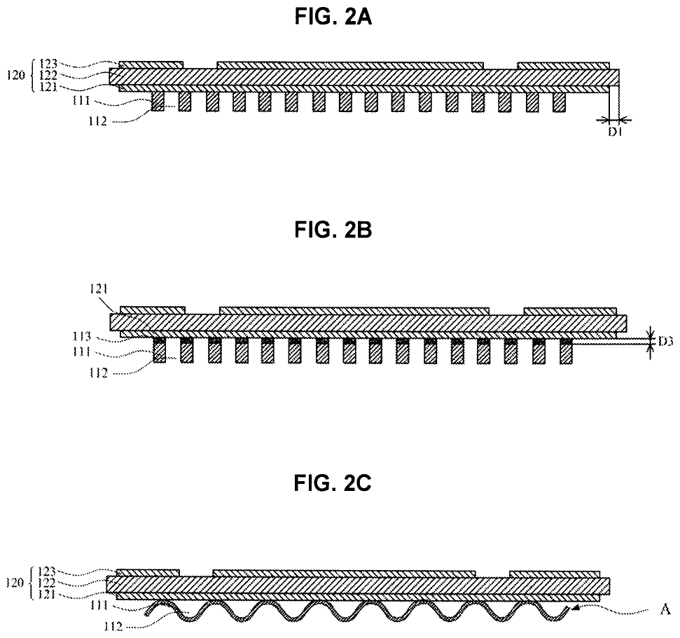

The heat radiating posts 111 may be formed in such a way that a screen mask or a stencil mask is used to mask the heat radiating metal layer 121, and metal paste or non-metal paste is directly printed onto the heat radiating metal layer 121, and then, is hardened. Accordingly, as illustrated in FIG. 2A, the heat radiating posts 111 and the heat radiating metal layer 121 may be directly bonded and joined to each other without a separate adhesive layer.

Also, in order to raise heat conductivity, the heat radiating posts 111 may be a solder containing Sn ingredient, may be formed of a single material including Al, Cu, or ceramic, or may be formed of a composite material containing 50% or more of any one of Sn, Al, Cu, and ceramic.

In addition, as illustrated in FIG. 2B, the heat radiating metal layer 121 and the heat radiating posts 111 may be bonded and joined to each other in such a way that adhesive layers 113 having excellent heat conductivity are interposed therebetween, wherein the adhesive layers 113 may be formed of a single material including Ag, Au, Cu, Ti, Ni, Pd, or ceramic or a composite material containing 50% or more of any one of Ag, Au, Cu, Ti, Ni, Pd, and ceramic.

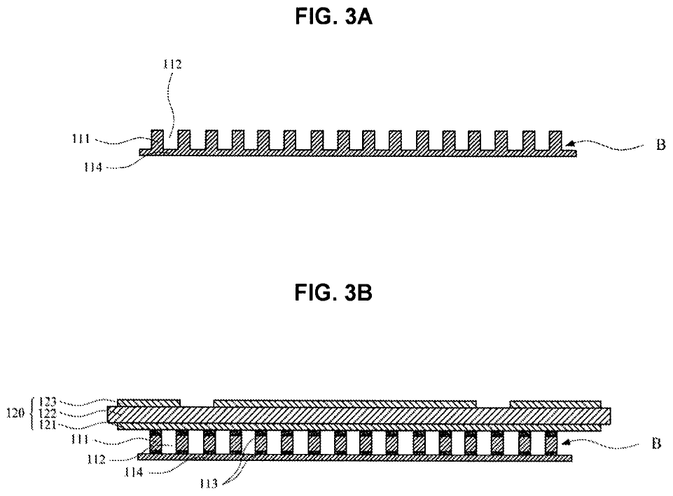

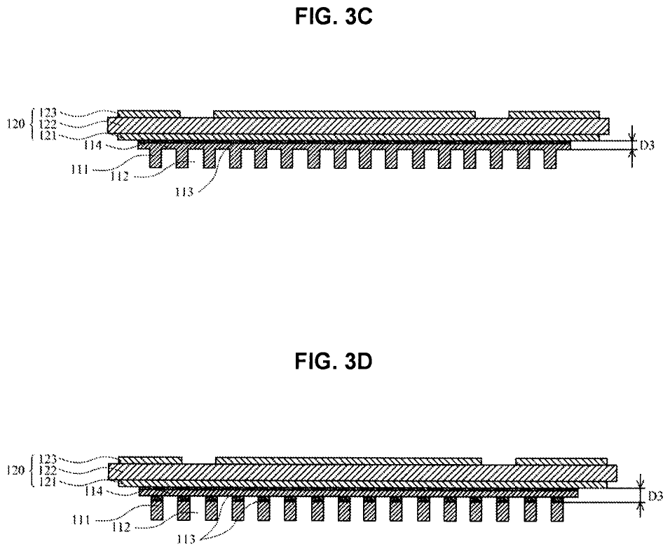

Here, referring to FIG. 2B and FIGS. 3C and 3D, a distance D3 where the adhesive layers 113 are interposed between the heat radiating metal layer 121 and the heat radiating posts 111 may be 10 μm through 3 mm.

Also, as illustrated in FIG. 2C, the heat radiating post 111 has at least one wave-form structure A where the crest of the wave is joined to the bottom surface of the heat radiating metal layer 121, the at least one post hole 112 may be formed between each neighbored crest between the heat radiating metal layer 121 and the wave-form structure A, and the wave-form structure A may be bonded to the heat radiating metal layer 121 by using ultrasonic welding.

In addition, as illustrated in FIG. 3A, at least one post connecting frame 114 is structurally bonded to one surface of the at least one heat radiating post 111 to form a post connection part B so that the post connection part B may be joined to the bottom surface of the heat radiating metal layer 121.

More specifically, in the post connection part B, the heat radiating posts 111 may be bonded to the post connecting frame 114 by using ultrasonic welding or as illustrated in FIG. 3B, the adhesive layers 113 are formed on the upper surfaces, the lower surfaces, or the upper and lower surfaces of the heat radiating posts 111 so that the heat radiating posts 111 may be joined to the heat radiating metal layer 121 and/or the post connecting frame 114.

As another example, while the post connection part B is flipped, the adhesive layer 113 is formed on the upper surface of the post connecting frame 114, as illustrated in FIG. 3C, so that the adhesive layer 113 may be joined to the bottom surface of the heat radiating metal layer 121. Also, as another example in FIG. 3D, the adhesive layer 113 is formed on the upper surface of the post connecting frame 114 and is joined to the bottom surface of the heat radiating metal layer 121. The heat radiating posts 111 and the post connecting frame 114 may be bonded to each other by using the adhesive layer 113 interposed therebetween.

At least one layered post connection part B may be formed on the bottom surface of the heat radiating metal layer 121 so that the coolant flow path formed by the post holes 112 is expanded to raise cooling efficiency.

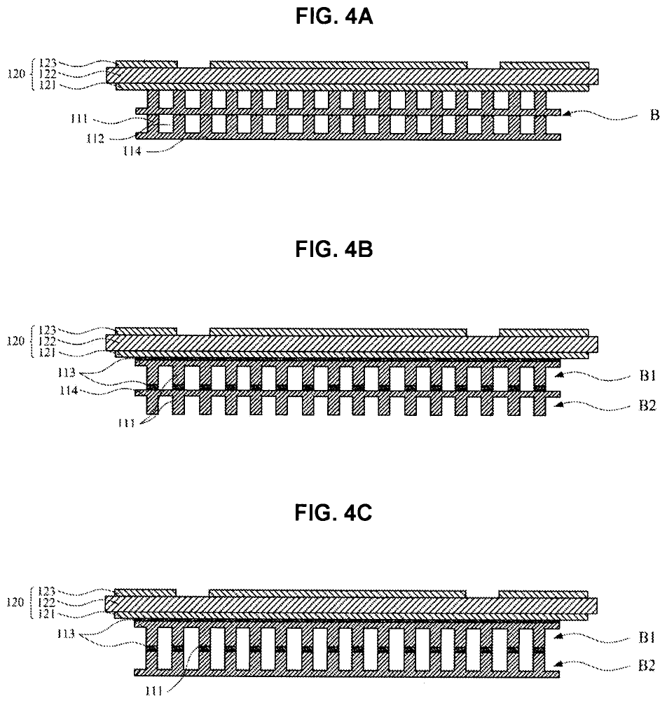

More specifically, illustrated in FIG. 4A, the heat radiating posts 111 may be sequentially stacked in the direction the heat radiating posts 111 are joined to the heat radiating metal layer 121, or as illustrated in FIG. 4B, the post connecting frame 114 of an upper post connection part B1 may be bonded to the bottom surface of the heat radiating metal layer 121 by using the adhesive layer 113 interposed therebetween and the heat radiating posts 111 of the upper post connection part B1 may be bonded to the post connecting frame 114 of a lower post connection part B2 by using the adhesive layer 113 interposed therebetween. As illustrated in FIG. 4C, the heat radiating posts 111 of the upper post connection part B1 may be joined to the heat radiating posts 111 of the flipped lower post connection part B2 by using the adhesive layer 113 interposed therebetween.

Also, as illustrated in an enlarged view of FIG. 1, a first distance D4 from the lower end part of the insulating layer 122 to the upper end part of the heat radiating metal layer 121 may be shorter than a second distance D5 from the lower end part of the insulating layer 122 to the lower end part of the heat radiating metal layer 121. More preferably, a gap D6 between the first distance D4 and the second distance D5 may be 1 μm through 200 μm. Since the second distance D5 from the lower end part of the insulating layer 122 to the lower end part of the heat radiating metal layer 121 is formed to be longer than the first distance D4 from the lower end part of the insulating layer 122 to the upper end part of the heat radiating metal layer 121, a material of the molding housing 140 may be easily filled during forming of the molding housing 140 after bonding of the semiconductor chips 130 and stress generated due to a difference of a coefficient of thermal expansion (CTE) may be easily endured. In addition, heat generated from the semiconductor chips 130 may be efficiently radiated to the outside due to formation of the second distance D5 to be longer than the first distance D4.

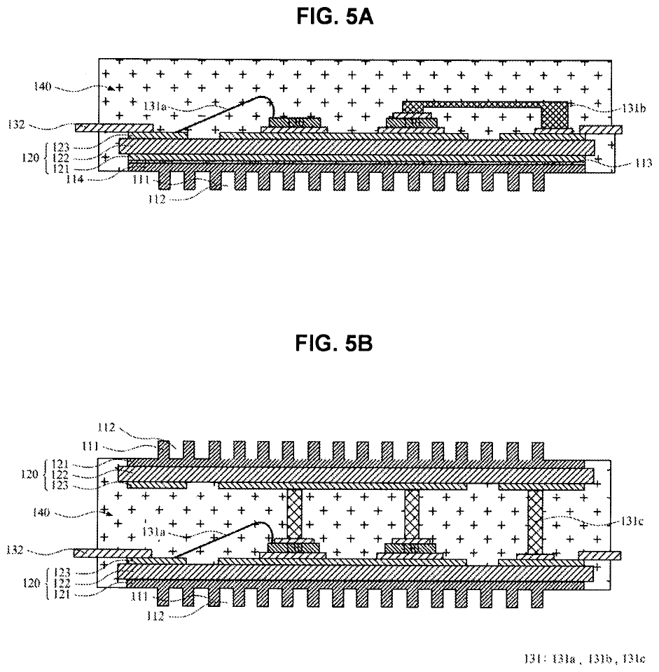

FIGS. 5A and 5B illustrate various structures of the semiconductor package including a heat radiation of FIG. 1. FIG. 5A illustrates a single-sided substrate where the heat radiating metal layer 121 and the post connecting frame 114 are bonded to each other by using the adhesive layer 113 interposed therebetween, and a part of or entire post connecting frame 114 is inserted into the molding housing 140. FIG. 5B illustrates a double-sided substrate where the heat radiating metal layer 121 is bonded to the insulating layer 122 and metal spacers 131C are used to space the substrates apart from each other upward and downward.

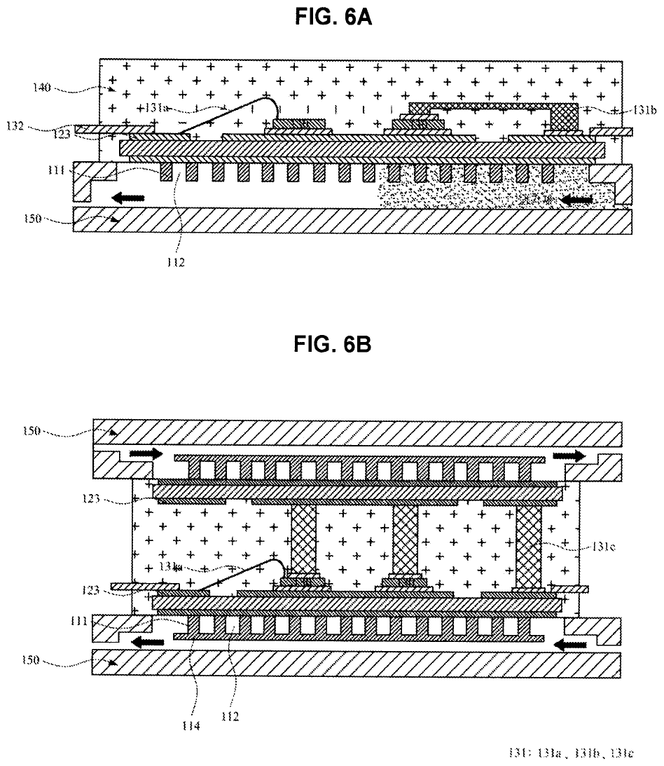

FIGS. 6A and 6B illustrate a cooling structure between the semiconductor package including a heat radiation of FIG. 1 and a cooling system. FIG. 6A illustrates that the cooling system 150 is bonded to one surface of a single-sided substrate and FIG. 6B illustrates that the cooling systems 150 are bonded to both sides of the both-sided substrate. Referring to FIG. 6B, the post connecting frame 114 is inserted into the cooling system 150 and an area contacting the circulating coolant is enlarged so that cooling efficiency may be improved.

The electrical signal line 131 mentioned above may be a wire 131A, a metal clip 131B formed by bending a metal plate, or the metal spacer 131C.

Referring to FIGS. 6A and 6B, the cooling system 150 where the semiconductor package including a heat radiation structure described above is joined is provided according to another embodiment of the present invention.

Also, referring to FIGS. 2A to 2C, in another embodiment of the present invention, a substrate including a heat radiation structure includes the heat radiating metal layer 121 to which the heat radiating posts 111 are structurally joined, the at least one insulating layer 122 stacked on the heat radiating metal layer 121, and the metal pattern layer 123 stacked on the insulating layer 122, wherein the metal pattern layer 123 includes the semiconductor chips 130 installed thereon. An area of the insulating layer 122 is larger than an area of the heat radiating metal layer 121, the insulating layer 122 is extended outward from the edge of the heat radiating metal layer 121 by the extended distance D1 of 5 μm through 3 mm, at least one post hole 112 is interposed between the heat radiating posts 111 which are arranged and spaced apart from each other by a regular interval so as to form the coolant flow path, and a coolant of the cooling system 150 used to cool heat generated from the semiconductor chips 130 circulates the coolant flow path.

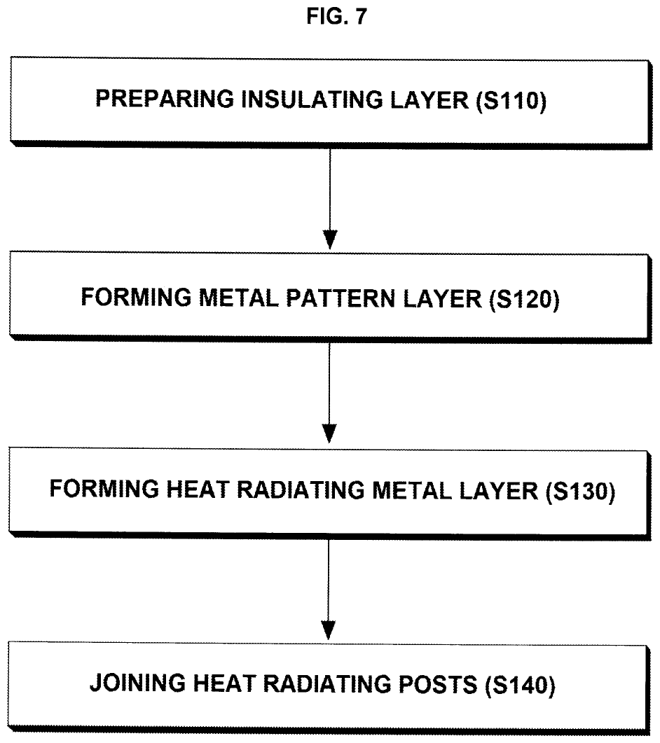

FIG. 7 is a flowchart schematically illustrating a method of manufacturing a substrate including a heat radiation structure according to another embodiment of the present invention. Referring to FIG. 7, the method of manufacturing a substrate including a heat radiation structure includes preparing the at least one insulating layer 122 in operation S110, forming the metal pattern layer 123 where the semiconductor chips 130 are installed on one surface of the insulating layer 122 in operation S120, forming the heat radiating metal layer 121 on the other surface of the insulating layer 122 in operation S130, and structurally joining the heat radiating posts 111 to the heat radiating metal layer 121 in operation S140, wherein an area of the insulating layer 122 is larger than an area of the heat radiating metal layer 121, the insulating layer 122 is extended outward from the edge of the heat radiating metal layer 121 by the extended distance D1 of 5 μm through 3 mm, at least one post hole 112 is interposed between the heat radiating posts 111 which are arranged and spaced apart from each other by a regular interval so as to form the coolant flow path, and a coolant of the cooling system 150 used to cool heat generated from the semiconductor chips 130 circulates the coolant flow path.

According to the present invention, an area contacting a coolant enlarges through the heat radiating posts having various forms and structures and a coolant flow path is formed by the post holes so that heat generated from the semiconductor chips may be efficiently cooled. Also, the heat radiating metal layer is covered by the insulating layer so that heat transmitted to the heat radiating posts may not be retransmitted, and the cooling system for cooling the heat radiating posts may be respectively applied to a single-sided substrate and a double-sided substrate.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package having a heat radiation structure, the semiconductor package comprising:
at least one substrate comprising a heat radiating metal layer, to which heat radiating posts are structurally joined, and at least one insulating layer;
at least one semiconductor chip comprising a lower surface bonded to the substrate and an upper surface electrically connected to a terminal lead through an electrical signal line; and
a molding housing covering the semiconductor chips, a part of the terminal lead, and a part of or the entire substrate,
wherein the heat radiating posts are formed to be exposed to the upper surface, the lower surface, or the upper and lower surfaces of the molding housing, an area of the insulating layer is larger than an area of the heat radiating metal layer, the insulating layer is extended outward from the edge of the heat radiating metal layer by a predetermined extended distance in the molding housing, a distance from the bottom of the insulating layer to the bottom of the molding housing, where the heat radiating posts are exposed, is 40 μm through 4 mm, at least one post hole is interposed between the heat radiating posts which are arranged and spaced apart from each other by a regular interval so as to form a coolant flow path, and a coolant of a cooling system used to cool heat generated from the semiconductor chips circulates the coolant flow path.

2. The semiconductor package of claim 1, wherein the at least one substrate comprises the at least one heat radiating metal layer, the insulating layer stacked on the heat radiating metal layer, and a metal pattern layer comprising the semiconductor chips installed thereon which is stacked on the insulating layer.

3. The semiconductor package of claim 2, wherein a metal adhesive layer having a thickness thinner than the thickness of the metal pattern layer or the heat radiating metal layer is interposed between the insulating layer and the metal pattern layer or between the insulating layer and the heat radiating metal layer.

4. The semiconductor package of claim 1, wherein the heat radiating posts are formed by being masked using a screen mask or a stencil mask, printing metal paste or non-metal paste onto the heat radiating metal layer, and then, being hardened.

5. The semiconductor package of claim 1, wherein the heat radiating metal Layer and the heat radiating posts comprise an adhesive layer interposed therebetween to be joined to each other.

6. The semiconductor package of claim 1, wherein the heat radiating posts have at least one wave-form structure where the crest of the wave is joined to the bottom surface of the heat radiating metal layer and at least one post hole is formed between each neighbored crest between the heat radiating metal layer and the wave-form structure.

7. The semiconductor package of claim 6, wherein the wave-form structure is bonded to the heat radiating metal layer by using ultrasonic welding.

8. The semiconductor package of claim 1, wherein the at least one heat radiating post comprises at least one post connecting frame structurally joined to one surface thereof to form a post connection part.

9. The semiconductor package of claim 8, wherein the heat radiating posts comprise adhesive layers on the upper surfaces, the lower surfaces, or the upper and lower surfaces thereof.

10. The semiconductor package of claim 8, wherein the post connecting frame comprises an adhesive layer on the upper surface thereof.

11. The semiconductor package of claim 8, wherein the heat radiating metal layer comprises at least one layered post connection part stacked on the bottom surface thereof.

12. The semiconductor package of claim 1, wherein the distance between the heat radiating metal layer and the heat radiating posts is 10 μm through 3 mm.

13. The semiconductor package of claim 1, wherein a first distance from the lower end part of the insulating layer to the upper end part of the heat radiating metal layer is shorter than a second distance from the lower end part of the insulating layer to the lower end part of the heat radiating metal layer.

14. The semiconductor package of claim 13, wherein a gap between the first distance and the second distance is 1 μm through 200 μm.

15. The semiconductor package of claim 8, wherein the post connecting frame is inserted into the cooling system.

16. The semiconductor package of claim 1, wherein the heat radiating metal layer and the heat radiating posts are formed of the same material.

17. The semiconductor package of claim 1, wherein the extended distance is 5 μm through 3 mm.

18. The semiconductor package of claim 1, wherein the heat radiating posts are joined to the substrate after a molding process of the molding housing.

19. A substrate having a heat radiating structure comprising:
a heat radiating metal layer to which heat radiating posts are structurally joined; and
the at least one insulating layer stacked on the heat radiating metal layer,
wherein an area of the insulating layer is larger than an area of the heat radiating metal layer, the insulating layer is extended outward from the edge of the heat radiating metal layer by a predetermined extended distance, at least one post hole is interposed between the heat radiating posts which are arranged and spaced apart from each other by a regular interval so as to form a coolant flow path, and a coolant of a cooling system circulates the coolant flow path.

20. A method of manufacturing a substrate having a heat radiating structure, the method comprising:
preparing at least one insulating layer;
forming a heat radiating metal layer on one surface of the insulating layer; and
structurally joining the heat radiating posts to the heat radiating metal layer,
wherein an area of the insulating layer is larger than an area of the heat radiating metal layer, the insulating layer is extended outward from the edge of the heat radiating metal layer by a predetermined extended distance, at least one post hole is interposed between the heat radiating posts which are arranged and spaced apart from each other by a regular interval so as to form a coolant flow path, and a coolant of a cooling system circulates the coolant flow path.
